(19) United States
(12) Patent Application Publication
(10) Pub. No.: US 2024/0347340 A1
(43) Pub. Date: Oct. 17, 2024

(54) EPITAXIAL STRUCTURE AND METHOD OF FORMING THE SAME

(71) Applicants: TAIWAN SEMICONDUCTOR MANUFACTURING COMPANY, LTD., Hsinchu (TW); NATIONAL YANG MING CHIAO TUNG UNIVERSITY, Hsinchu City (TW)

(72) Inventors: Shu-Jui CHANG, Hsinchu County (TW); Shin-Yuan WANG, Chiayi City (TW); Yu-Che HUANG, Taipei City (TW); Chao-Hsin CHIEN, Hsinchu City (TW); Chenming HU, Oakland, CA (US)

(73) Assignees: TAIWAN SEMICONDUCTOR MANUFACTURING COMPANY, LTD., Hsinchu (TW); NATIONAL YANG MING CHIAO TUNG UNIVERSITY, Hsinchu City (TW)

(21) Appl. No.: 18/299,610

(22) Filed: Apr. 12, 2023

(51) Int. Cl. H01L 21/20; H01L 21/02; H01L 21/768; H01L 29/417; H01L 29/51

(52) U.S. Cl. CPC H01L 21/20; H01L 21/02175; H01L 21/76829; H01L 29/41725; H01L 29/516

(57) ABSTRACT

An epitaxial structure includes a substrate and a dielectric layer. The dielectric layer is on the substrate. The substrate comprises a single crystal metal or a single crystal 2D material. The dielectric layer is in physical contact with the substrate. The dielectric layer comprises a non-perovskite structure with defined grain orientation with ferroelectric (FE) phase or antiferroelectric (AFE) phase.

### BACKGROUND

The semiconductor integrated circuit (IC) industry has experienced rapid growth. In the course of IC evolution, functional density (i.e., the number of interconnected devices per chip area) has increased while geometry size (i.e., the smallest component (or line) that can be created using a fabrication process) has decreased. This scaling down process increases production efficiency and lowers associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are a cross-sectional view of forming an epitaxial structure in accordance with some embodiments.

FIGS. 3A and 3B are top views of a crystal structure of the epitaxial structure of FIG. 2 in accordance with some embodiments.

FIGS. 4A and 4B are tables showing the property of crystal structures of the substrate and the dielectric layer, respectively, in accordance with some embodiments.

FIGS. 5A and 5B are side views of a crystal structure of the epitaxial structure of FIG. 2 in accordance with some embodiments.

FIG. 6 is a cross-sectional view of a metal-ferroelectric-metal (MFM) structure in accordance with some embodiments.

FIG. 7 is a cross-sectional view of a semiconductor-ferroelectric-metal (SFM) structure in accordance with some embodiments.

FIG. 8 is a cross-sectional view of a metal-ferroelectric-semiconductor (MFS) structure in accordance with some embodiments.

FIG. 9 is a cross-sectional view of a metal-ferroelectric-insulator-semiconductor (MFIS) structure in accordance with some embodiments.

FIG. 10 is a cross-sectional view of a back-gate FE transistor in accordance with alternative embodiments.

FIGS. 11-15 are cross-sectional views of a method of manufacturing a semiconductor device at various stages in accordance with some embodiments.

FIG. 16 is a cross-sectional view of a negative capacitance field effect transistor (NCFET) in accordance with some embodiments.

FIGS. 17-20, 23B, 26B and 27B illustrate cross-sectional views that extend through a gate stack (see the gate stack in FIG. 30) along a longitudinal axis of the gate stack.

FIGS. 21, 22, 23A, 24, 25, 26A, 27A, 28, 29 and 30 illustrate cross-sectional views that extend through a fin structure (see the fin structure in FIG. 18) along a longitudinal axis of the fin.

FIG. 31 is a cross-sectional view of a semiconductor device in accordance with some embodiments.

FIG. 32 is a cross-sectional view of a semiconductor device in accordance with some embodiments.

FIG. 33 is a cross-sectional view of a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

A ferroelectric material (e.g., doped hafnium oxide) deposited on a semiconductor material or a metal material may include polycrystalline grains with non-uniform ferroelectric phase distribution. For example, methods to deposit the ferroelectric material may result in the polycrystalline ferroelectric materials with random grain boundaries and multiple-phase such as monoclinic, orthorhombic, tetragonal phases. Such non-uniform ferroelectric material is not ideal for manufacturing highly uniform devices for high yield integrated circuit (IC) fabrication. Electric characteristics of ferroelectric field-effect transistor (FE-FET) are influenced by FE domains distribution, which may cause threshold voltage (Vₜ) fluctuation. Epitaxial ferroelectric material may be deposited on a 3D single crystalline La₁₋ₓSrₓMnO₃ substrate. However, La₁₋ₓSrₓMnO₃ substrate is rarely used in a wide variety of commercial electronic devices.

Embodiments of the present disclosure relate to forming a single crystal dielectric layer with defined grain orientation with ferroelectric phase or antiferroelectric phase on a single crystal substrate.

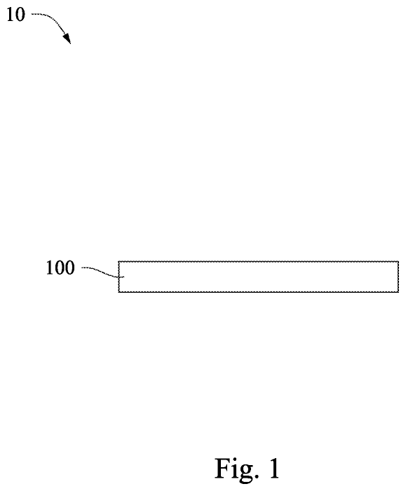

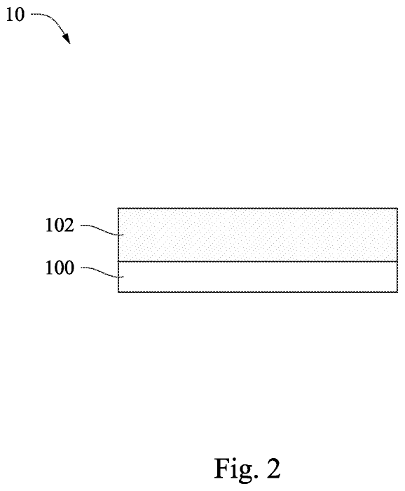

FIGS. 1 and 2 are a cross-sectional view of forming an epitaxial structure 10 in accordance with some embodiments. Reference is made to FIG. 1. In some embodiments, a substrate 100 is a single crystal substrate. In other words, the substrate 100 includes a crystal lattice being continuous and with no grain boundaries therein. The substrate 100 has a property preserved by a crystal orientation of the crystal lattice, not preserved by the grain boundaries. In some embodiments, the substrate 100 is a single crystal metal, a single crystal 2D material such as 2D metallic material, a 2D dielectric, or a 2D semiconductor. In some embodiments where the substrate 100 is a single crystal metal, the substrate 100 may be single crystal Hf, single crystal Mo or single crystal W. In some embodiments where the substrate 100 is a single crystal 2D semiconductor, the substrate 100 may be single crystal MoS₂, single crystal WS₂, or single crystal WSe₂. In some embodiments where the substrate 100 is a single crystal 2D dielectric, the substrate 100 may be single crystal h-AlN. In some embodiments where the substrate 100 is a single crystal 2D metallic material, the substrate 100 may be layered Hf.

Reference is made to FIG. 2. A dielectric layer 102 is formed on the substrate 100 and is in physical contact with the substrate 100. The dielectric layer 102 is epitaxially grown on the substrate 100. The dielectric layer 102 is a single crystal dielectric layer. In other words, the dielectric layer 102 includes a crystal lattice being continuous and with no grain boundaries therein. The dielectric layer 102 has a property preserved by a crystal orientation of the crystal lattice, not preserved by the grain boundaries. In some embodiments, the dielectric layer 102 is a non-perovskite structure with defined grain orientation with ferroelectric (FE) phase or antiferroelectric (AFE) phase. That is, the dielectric layer 102 is a ferroelectric layer or an antiferroelectric layer. For example, the dielectric layer 102 is an orthorhombic single crystal with a defined grain orientation with FE phase or AFE phase. In some embodiments, the dielectric layer 102 includes doped HfO₂, ZrO₂, Hf₁₋ₓZrₓO₂ where 0<x<1, with a defined grain orientation with FE phase or AFE phase.

By forming the dielectric layer 102 on the substrate 100 which is a single crystal substrate and has a lattice constant similar to a lattice constant of the dielectric layer, the dielectric layer 102 can be formed as with defined grain orientation with ferroelectric phase or antiferroelectric phase. As discussed previously, the substrate 100 includes a single crystal 2D material such as 2D metallic material, a 2D dielectric, or a 2D semiconductor, or includes a single crystal metal such as single crystal Hf, single crystal Mo or single crystal W, which are used in a wide variety of commercial electronic devices, and thus is compatible with a commercial process flow.

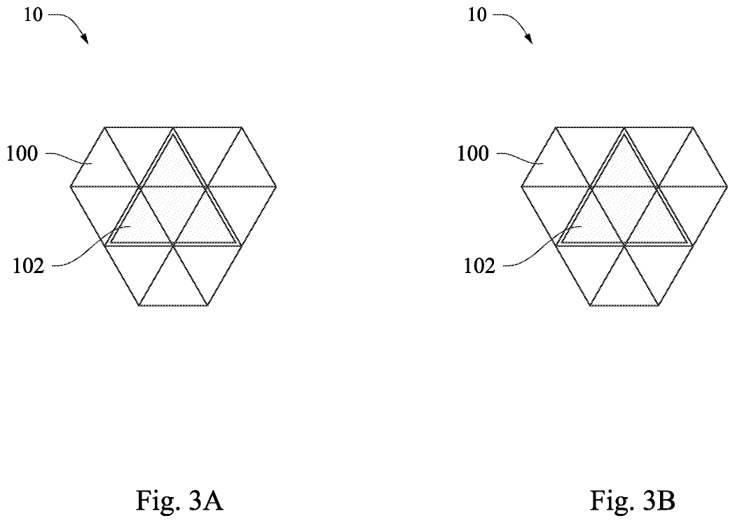

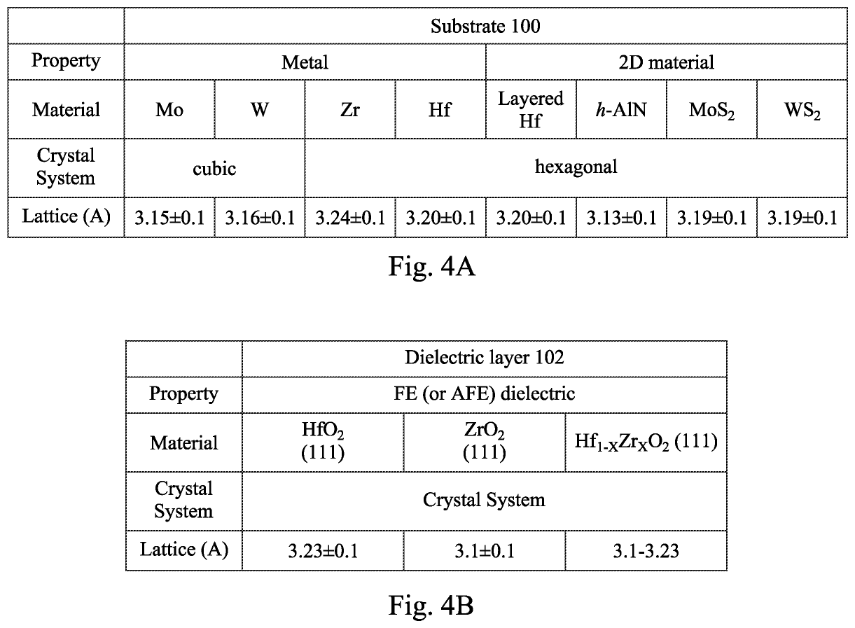

FIGS. 3A and 3B are top views of a crystal structure of the epitaxial structure 10 of FIG. 2 in accordance with some embodiments. FIGS. 4A and 4B are tables showing the property of crystal structures of the substrate 100 and the dielectric layer 102, respectively, in accordance with some embodiments. Reference is made to FIGS. 2, 3A, 4A and 4B. The dielectric layer 102 has a cubic crystal structure and has a (111) surface orientation with a lattice constant similar to a lattice constant of the substrate 100 such that the dielectric layer 102 can be epitaxy grown on the substrate 100. In some embodiments, the dielectric layer 102 is a HFO₂ layer having a (111) surface orientation with a lattice constant of 3.23±0.1 Å. In some embodiments, the dielectric layer 102 is a ZrO₂ layer having a (111) surface orientation with a lattice constant of 3.1±0.1 Å. In some embodiments, the dielectric layer 102 is a Hf₁₋ₓZrₓO₂ layer where 0<x<1 having a (111) surface orientation with a lattice constant in a range from 3.1 Å to 3.23 Å.

In some embodiments, the substrate 100 is the single crystal metal having a cubic crystal structure or a hexagonal crystal structure. In some embodiments, the substrate 100 and the dielectric layer 102 have the same crystal system. For example, the substrate 100 is Mo having a cubic crystal structure with a lattice constant of 3.15±0.1 Å. For example, the substrate 100 is W having a cubic crystal structure with a lattice constant of 3.16±0.1 Å. In some embodiments, the substrate 100 and the dielectric layer 102 have different crystal systems. For example, the substrate 100 is Zr having a hexagonal crystal structure with a lattice constant of 3.24±0.1 Å. For example, the substrate 100 is Hf having a hexagonal crystal structure with a lattice constant of 3.20±0.1 Å.

Reference is made to FIGS. 2, 3B and 4A. The crystal structure in FIG. 3B is similar to the crystal structure with regard to FIG. 3A, except for the substrate 100 being the single crystal 2D material. For example, the substrate 100 is layered Hf having a hexagonal crystal structure with a lattice constant of 3.20±0.1 Å. For example, the substrate 100 is h-AlN having a hexagonal crystal structure with a lattice constant of 3.13±0.1 Å. For example, the substrate 100 is MoS₂ having a hexagonal crystal structure with a lattice constant of 3.19±0.1 Å. For example, the substrate 100 is WS₂ having a hexagonal crystal structure with a lattice constant of 3.19±0.1 Å. In some embodiments where the substrate 100 is single crystal 2D material, the substrate 100 can be prepared by epitaxially growing the single crystal 2D material such as using chemical vapor deposition (CVD) on a carrier substrate followed by detaching the single crystal 2D material from the carrier substrate. In some embodiments, the carrier substrate is silicon or sapphire.

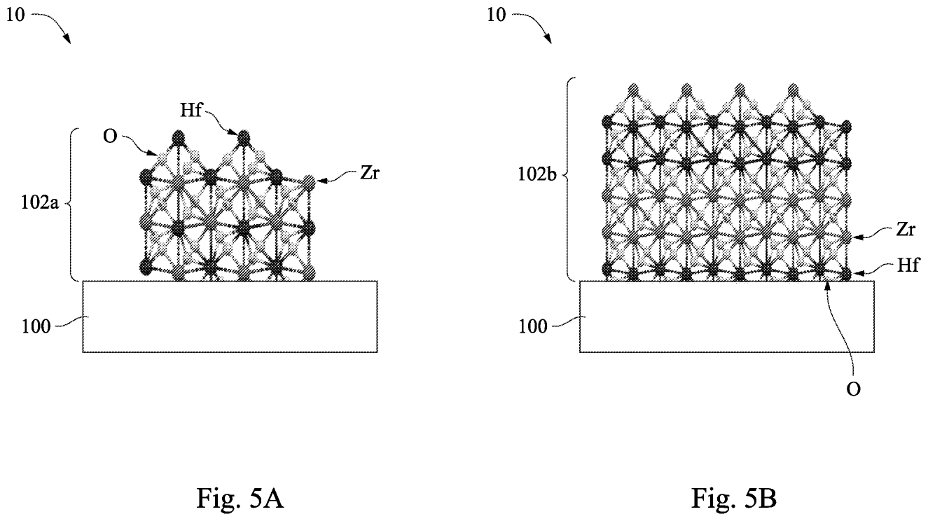

FIGS. 5A and 5B are side views of a crystal structure of the epitaxial structure 10 of FIG. 2 in accordance with some embodiments. Reference is made to FIG. 5A. In some embodiments, formation of the dielectric layer 102a includes depositing a dielectric material on the substrate 100 followed by a doping process. For example, a deposition process is performed to form a dielectric material including hafnium oxide using atomic layer deposition (ALD), metal organic chemical vapor deposition (MOCVD), or molecular beam epitaxy (MBE). The doping process is performed using dopants such as Zr or the like to form the dielectric layer 102a. During the doping process, the dopants are introduced into the dielectric material randomly. The hafnium oxide doped with zirconium forms a solid solution of hafnium oxide and zirconium oxide. Therefore, the resultant dielectric layer 102a may have the formula: Hf₁₋ₓZrₓO₂ where 0<x<1. In FIG. 5A, O is oxygen atoms, Hf is Hf atoms, and Zr is Zr atoms.

Reference is made to FIG. 5B. The dielectric layer 102b is similar to the dielectric layer 102a with regard to FIG. 5A, except for the dielectric layer 102b being formed by a layer-by-layer deposition method. Therefore, the dielectric layer 102b is formed by oxygen monolayers, Zr monolayers and Hf monolayers. A monolayer is defined as a single layer of complete coverage for the material. For example, a deposition process can be performed to form the monolayer of oxygen atoms, the monolayer of Zr atoms and the monolayer of Hf atoms using ALD, MOCVD, MBE or the like. Therefore, the resultant dielectric layer 102b may be formed by stacked oxygen monolayers, Hf monolayers and Zr monolayers.

Referring back to FIG. 2, the epitaxial structure 10 can be applied to form a memory cell structure, for example, a ferroelectric memory cell structure. Exemplary examples of the ferroelectric memory cell include metal-ferroelectric-metal (MFM) structure, semiconductor-ferroelectric-metal (SFM) structure, metal-ferroelectric-semiconductor (MFS) structure and metal-ferroelectric-insulator-semiconductor (MFIS) structure for ferroelectric random access memory (FeRAM).

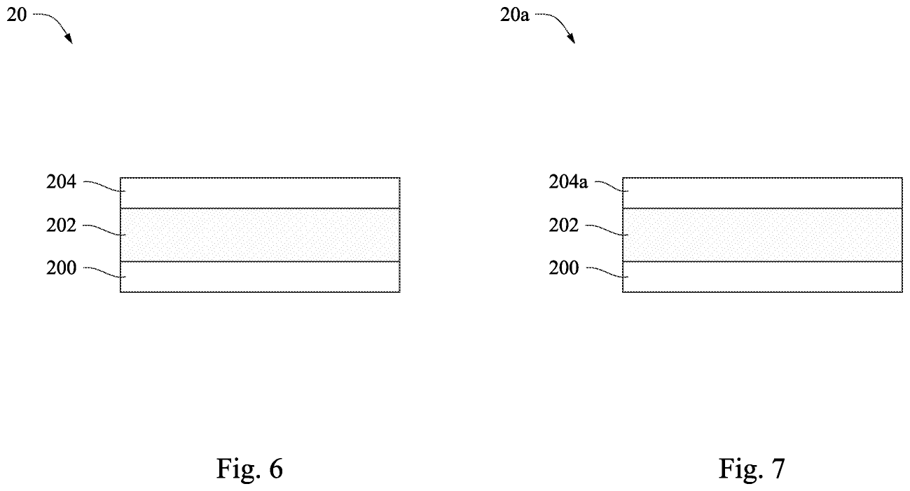

FIG. 6 is a cross-sectional view of a metal-ferroelectric-metal (MFM) structure 20 in accordance with some embodiments. Reference is made to FIG. 6. The MFM structure 20 includes a substrate 200, a dielectric layer 202 and a top electrode 204 stacked in sequence. The substrate 200 is a single crystal metal such as single crystal Hf, single crystal Mo or single crystal W. The substrate 200 acts as a bottom electrode. The dielectric layer 202 is similar to the dielectric layer 102 with regard to FIG. 2 in terms of composition and formation, and thus the description thereof is omitted. The dielectric layer 202 is a single crystal dielectric layer with ferroelectric (FE) phase or antiferroelectric (AFE) phase. In some embodiments, the top electrode 204 includes titanium nitride (e.g., TiN), tantalum nitride (e.g., TaN), platinum (e.g., Pt), titanium (e.g., Ti), tantalum (e.g., Ta), tungsten (e.g., W), iron (e.g., Fe), nickel (e.g., Ni), beryllium (e.g., Be), chromium (e.g., Cr), cobalt (e.g., Co), antimony (e.g., Sb), iridium (e.g., Ir), molybdenum (e.g., Mo), osmium (e.g., Os), thorium (e.g., Th), vanadium (e.g., V), an alloy thereof or a combination thereof. The dielectric layer 202 acts as a ferroelectric layer in the MFM structure 20. The substrate 200 and the top electrode 204 may be used to apply an electric field to the dielectric layer 202. A voltage may be applied across the dielectric layer 202 by holding the substrate 200 and the top electrode 204 at potentials to achieve the voltage. The dielectric layer 202 may become polarized and reach a polarization state in response to the applied electric field. The MFM structure 20 can define a capacitance as a capacitance in one-capacitor-one-transistor (1T1C) memory structure or some other suitable type of memory structure.

FIG. 7 is a cross-sectional view of a semiconductor-ferroelectric-metal (SFM) structure 20a in accordance with some embodiments. The SFM structure 20a is similar to the MFM structure 20 with regard to FIG. 6, except for the top electrode 204a including semiconductor. Reference is made to FIG. 7. The SFM structure 20a includes a substrate 200, a dielectric layer 202 and a top electrode 204a stacked in sequence. The top electrode 204a may include silicon, germanium, a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide, or a combination thereof.

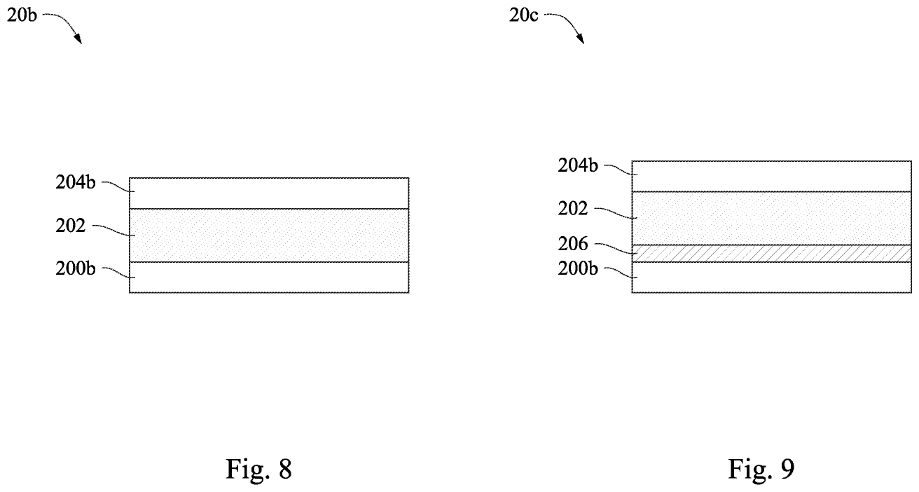

FIG. 8 is a cross-sectional view of a metal-ferroelectric-semiconductor (MFS) structure 20b in accordance with some embodiments. The MFS structure 20b is similar to the MFM structure 20 with regard to FIG. 6, except for the substrate 200b including 2D material and the top electrode 204b including semiconductor. Reference is made to FIG. 8. As discussed previously with regard to FIG. 1, in some embodiments, the substrate 200b is a single crystal 2D material such as 2D metallic material, a 2D dielectric, or a 2D semiconductor. In some embodiments where the substrate 200b is a single crystal 2D semiconductor, the substrate 200b may be single crystal MoS₂, single crystal WS₂, or single crystal WSe₂. In some embodiments where the substrate 200b is a single crystal 2D dielectric, the substrate 200b may be single crystal h-AlN. In some embodiments where the substrate 200b is a single crystal 2D metallic material, the substrate 200b may be layered Hf. The top electrode 204b has a material similar to the material of the top electrode 204a, and thus the description thereof is omitted.

FIG. 9 is a cross-sectional view of a metal-ferroelectric-insulator-semiconductor (MFIS) structure 20c in accordance with some embodiments. The MFIS structure 20c is similar to the MFS structure 20b with regard to FIG. 8, except for further including a crystalline insulator 206. The crystalline insulator 206 is disposed between the substrate 200b and the dielectric layer 202. In some embodiments, the crystalline insulator 206 may be AlN or transition metal dichalcogenide (TMD) material. The crystalline insulator 206 may be a high-k layer. The crystalline insulator 206 includes a lattice constant similar to the underlying substrate 200b and the overlying dielectric layer 202 such that the crystalline insulator 206 can be epitaxy grown on the substrate 200b, and the dielectric layer 202 can epitaxy grown on the crystalline insulator 206.

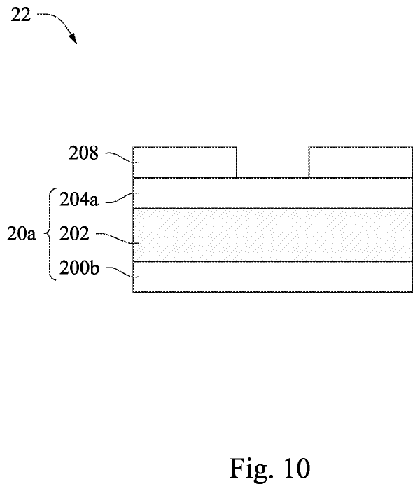

FIG. 10 is a cross-sectional view of a back-gate FE transistor 22 in accordance with alternative embodiments. Unless specified otherwise, the materials and the formation methods of the components in these embodiments are essentially the same as the like components, which are denoted by like reference numerals in the embodiments shown in FIG. 7. The details of the like components shown in FIG. 10 may thus be found in the discussion of the embodiments shown in FIG. 7. The back-gate FE transistor 22 can be formed by forming source/drain electrodes 208 on the SFM structure 20a with regard to FIG. 7. The source/drain electrodes 208 may be a conductive layer such as a metal layer containing an element such as Al, Cr, Cu, Ta, Ti. Mo, and W or a metal nitride layer containing any of the above elements.

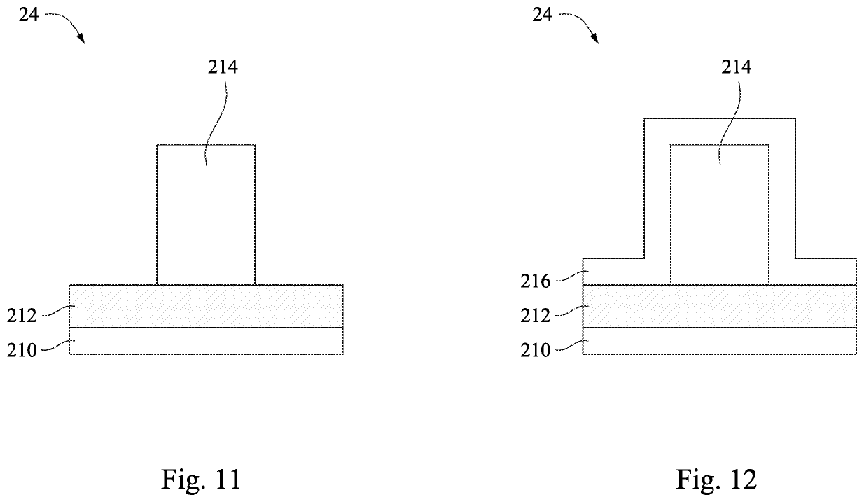

FIGS. 11-15 are cross-sectional views of a method of manufacturing a semiconductor device 24 at various stages in accordance with some embodiments. Reference is made to FIG. 11. A dielectric layer 212 is formed on a substrate 210. A gate electrode 214 is formed on the dielectric layer 212 by one or more suitable process including, but not limited to, deposition, photolithography, and/or etching processes. The substrate 210 is a single crystal 2D material such as 2D metallic material, a 2D dielectric, or a 2D semiconductor, as discussed previously with regard to FIG. 1. Therefore, the dielectric layer 212 is deposited as a single crystal dielectric layer, as discussed previously with regard to FIG. 2. The dielectric layer 212 is a single crystal dielectric layer with ferroelectric (FE) phase or antiferroelectric (AFE) phase. In some embodiments, the dielectric layer 212 includes doped HfO₂, ZrO₂, Hf₁₋ₓZrₓO₂ where 0<x<1, with a defined grain orientation with FE phase or AFE phase.

The gate electrode 214 may include a work function layer and a fill metal on the work function layer (not separately illustrated). The work function layer may include one or more p-type work function metals (P-metal) for forming a PMOS. P-type work function metal has a work function higher than the mid-gap work function (about 4.5 eV) that is in the middle of valance band and conduction band of silicon. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The work function layer may include one or more n-type work function metals (N-metal) for forming an n-type metal oxide semiconductor (NMOS). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. The fill metal may exemplarily include, but are not limited to, tungsten, aluminum, copper, nickel, cobalt, titanium, tantalum, titanium nitride, tantalum nitride, nickel silicide, cobalt silicide, TaC. TaSiN, TaCN, TiAl, TiAlN, or other suitable materials.

Reference is made to FIG. 12. A spacer layer 216 is conformally deposited over the gate electrode 214 and the dielectric layer 212. The spacer layer 216 is substantially conformal over a top surface and opposite sidewalls of the gate electrode 214 and over a top surface of the dielectric layer 212. The spacer layer 216 may include silicon nitride (SiN), silicon carbon-nitride (SiCN), silicon carbon-oxynitride (SiCON), the like, or a combination or multiple layers thereof, formed by CVD, ALD or the like.

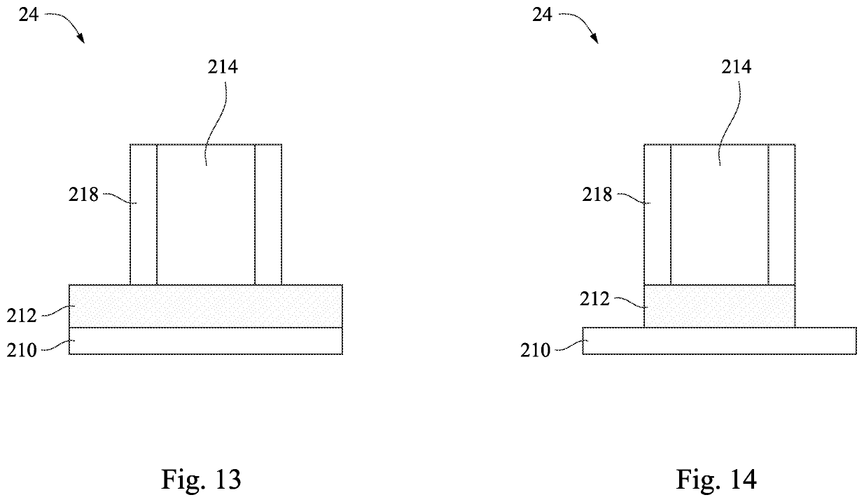

Reference is made to FIG. 13. The spacer layer 216 is etched to form gate spacers 218 on the opposite sidewalls of the gate electrode 214. The etch process for the spacer layer 216 includes an anisotropic etch process in some embodiments. The etch process for the spacer layer 216 may include coupled plasma (ICR) etch, transformer coupled plasma (TCP) etch, electron cyclotron resonance (ECR) etch, reactive ion etch (RIE), or the like. The etch process may be selective to the spacer layer 216, for example. The etch process is adapted to stop when the top surface of the dielectric layer 212 is exposed, in some embodiments. The etch process for the spacer layer 216 may also include other types of etch processes and processing parameters. The dielectric layer 212 is then patterned using the gate electrode 214 and the gate spacers 218 as an etch mask, exposing the substrate 210, using a plasma etch, for example. The resulting structure is shown in FIG. 14.

Recesses are formed in source/drain regions of the substrate 210 by etching the substrate 210. The recessing may include isotropic and/or anisotropic etching, wherein the gate spacers 218 and the gate electrode 214 act as an etching mask. The source/drain regions of the substrate 210 can be recessed using suitable selective etching processing that attacks the substrate 210, but hardly attacks the gate spacers 218 and the gate electrode 214. For example, recessing the substrate 210 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, a combination thereof, or the like, which etches the substrate 210 at a faster etch rate than it etches the gate spacers 218 and the gate electrode 214. In some other embodiments, recessing the substrate 210 may be performed by a combination of a dry chemical etch and a wet chemical etch.

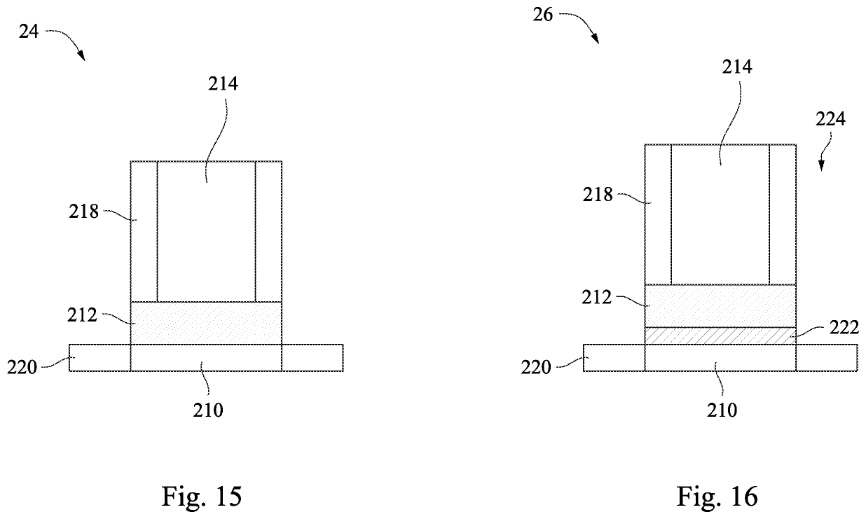

In FIG. 15, source/drain epitaxial structures 220 are formed in the recesses that are not covered by the gate electrode 214 and the gate spacers 218. In some embodiments, formation of the source/drain epitaxial structures 220 includes epitaxially growing semiconductor materials in the recesses of the substrate 210. The source/drain epitaxial structures 220 are on opposite sides of the gate electrode 214.

Once recesses are created in the source/drain regions of the substrate 210, source/drain epitaxial structures 220 are formed in the source/drain recesses 220 in the substrate 210 by using one or more epitaxy or epitaxial (epi) processes that provides one or more epitaxial materials on the substrate 210. In some embodiments, a lattice constants of the source/drain epitaxial structures 220 are different from a lattice constant of the substrate 210, so that a channel region in the substrate 210 and between the source/drain epitaxial structures 220 can be strained or stressed by the source/drain epitaxial structures 220 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), MBE, and/or other suitable processes. The source/drain epitaxial structures 220 are below the gate electrode 214 and abut the substrate 210.

In some embodiments, the source/drain epitaxial structures 220 may include Ge, Si, GaAs, AlGaAs, SiGe, GaAsP, SiP, or other suitable material. The source/drain epitaxial structures 220 may be in-situ doped during the epitaxy process by introducing doping species including: p-type dopants, such as boron or BF₂; n-type dopants, such as phosphorus or arsenic; and/or other suitable dopants including combinations thereof. If the source/drain epitaxial structures 220 are not in-situ doped, an implantation process (i.e., a junction implant process) is performed to dope the source/drain epitaxial structures 220. In some exemplary embodiments, the source/drain epitaxial structures 220 in an n-type transistor include SiP, while those in a p-type include GeSnB and/or SiGeSnB.

Once the source/drain epitaxial structures 220 are formed, an annealing process can be performed to activate the p-type dopants or n-type dopants in the source/drain epitaxial structures 220. The annealing process may be, for example, a rapid thermal anneal (RTA), a laser anneal, a millisecond thermal annealing (MSA) process or the like.

FIG. 16 is a cross-sectional view of a negative capacitance field effect transistor (NCFET) 26 in accordance with some embodiments. The NCFET 26 is similar to the top-gate FE transistor 24, except for further including a crystalline insulator 222 between the substrate 210 and the dielectric layer 212. The crystalline insulator 222, the dielectric layer 212 and the gate electrode 214 collectively construct a ferroelectric capacitor 224. The crystalline insulator 222 is similar to the crystalline insulator 206 in FIG. 9 in terms of composition, and thus the description thereof is omitted. The top-gate FE transistor 24 and the NCFET are planar FETs. In some embodiments, the epitaxial structure 10 with regard to FIG. 2 can be applied to GAA transistor structures.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

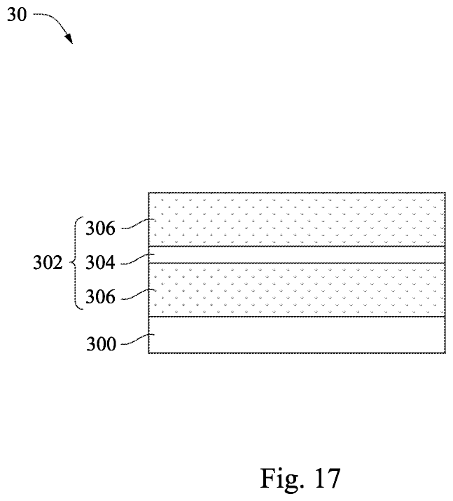

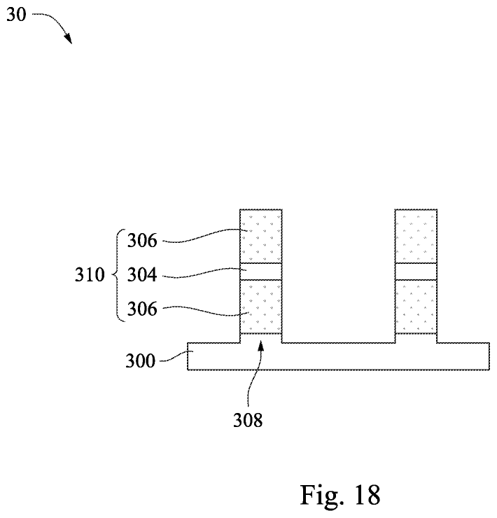

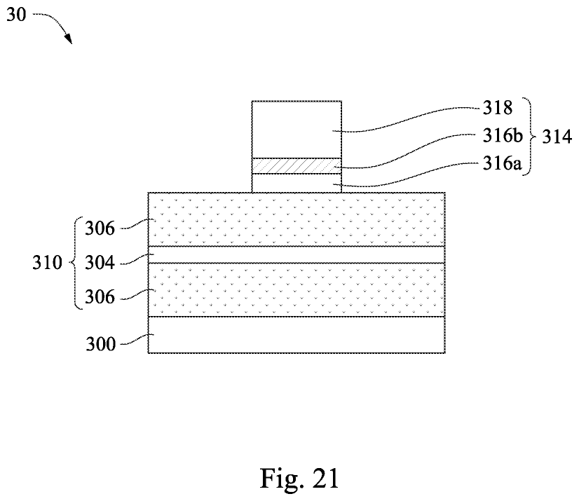

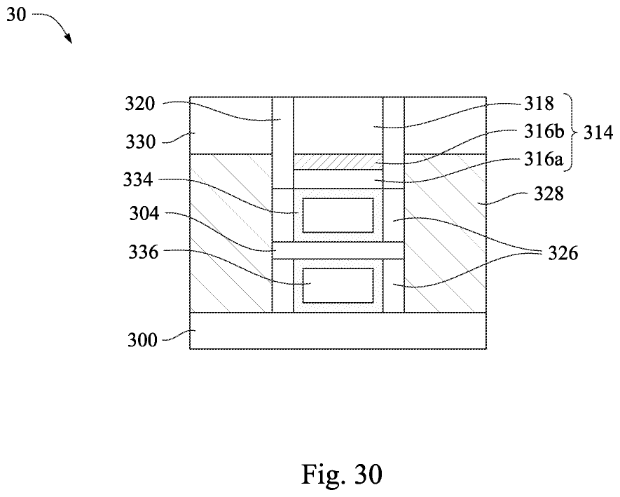

FIGS. 17-20, 23B, 26B and 27B illustrate cross-sectional views that extend through a gate stack (see the gate stack 314 in FIG. 30) along a longitudinal axis of the gate stack. FIGS. 21, 22, 23A, 24, 25, 26A, 27A, 28, 29 and 30 illustrate cross-sectional views that extend through a fin structure (see the fin structure 308 in FIG. 18) along a longitudinal axis of the fin. Reference is made to FIG. 17. A substrate 300 is provided. The substrate 300 may be a semiconductor substrate, such as a bulk semiconductor, a semiconductor-on-insulator (SOI) substrate, or the like, which may be doped (e.g., with a p-type or an n-type dopant) or undoped. The substrate 300 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 300 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 17, a multi-layer stack 302 is formed over the substrate 300. The multi-layer stack 302 includes a single crystal layer 304 sandwiched between sacrificial layers 306. For purposes of illustration and as discussed in greater detail below, the sacrificial layers 306 will be removed and the single crystal layer 304 will be patterned to form channel regions of GAA-FETs.

The multi-layer stack 302 is illustrated as including two layers of the sacrificial layers 306 and one layer of the single crystal layer 304 for illustrative purposes. In some embodiments, the multi-layer stack 302 may include any number of the sacrificial layers 306 and the single crystal layer 304. Each of the layers of the multi-layer stack 302 may be epitaxially grown using a process such as ALD, MOCVD, MBE or the like. In various embodiments, the single crystal layer 304 may be formed of a 2D semiconductor suitable for serving as channel regions of GAA-FETs, such as single crystal MoS₂, single crystal WS₂, or single crystal WSe₂. The single crystal layer 304 has a lattice constant similar to a lattice constant of a subsequently formed dielectric layer in order to advantageously allow the dielectric layer formed as a single crystal.

The sacrificial layers 306 and the single crystal layer 304 may include materials having a high-etch selectivity to one another. As such, the sacrificial layers 306 may be removed without significantly removing the single crystal layer 304, thereby allowing the single crystal layer 304 to serve as channel regions of GAA-FETs.

Referring now to FIG. 18, fin structures 308 are formed in the substrate 300 and nanostructures 310 are formed in the multi-layer stack 302, in accordance with some embodiments. In some embodiments, the nanostructures 310 and the fin structures 308 may be formed in the multi-layer stack 302 and the substrate 300, respectively, by etching trenches in the multi-layer stack 302 and the substrate 300. Each fin structure 308 and overlying nanostructures 310 can be collectively referred to as a fin extending from the substrate 300. The etching may be any acceptable etch process, such as a reactive ion etch (RIE), neutral beam etch (NBE), the like, or a combination thereof. The etching may be anisotropic.

The fin structures 308 and the nanostructures 310 may be patterned by any suitable method. For example, the fin structures 308 and the nanostructures 310 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 308.

While each of the fin structures 308 and the nanostructures 310 are illustrated as having a consistent width throughout, in other embodiments, the fin structures 308 and/or the nanostructures 310 may have tapered sidewalls such that a width of each of the fin structures 308 and/or the nanostructures 310 continuously increases in a direction towards the substrate 300. In such embodiments, each of the nanostructures 310 may have a different width and be trapezoidal in shape.

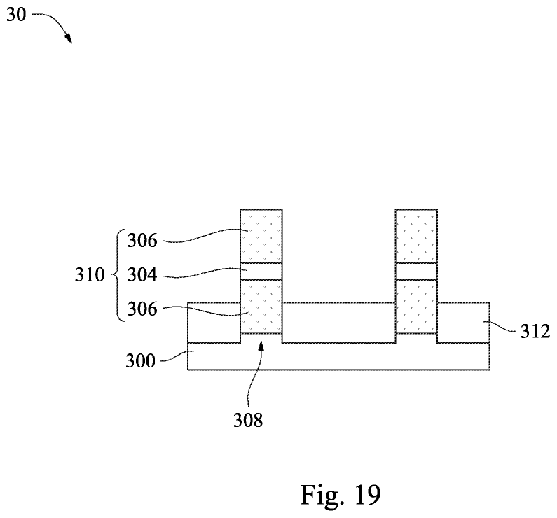

In FIG. 19, shallow trench isolation (STI) regions 312 are formed adjacent the fin structures 308 and the nanostructure 310. The STI regions 312 may be formed by depositing an insulation material over the substrate 300, the fin structures 308, and the nanostructures 310, and between adjacent fin structures 308. The insulation material may be an oxide, such as silicon oxide, a nitride, the like, or a combination thereof, and may be formed by high-density plasma CVD (HDP-CVD), flowable CVD (FCVD), or the like. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 310. Although the insulation material is illustrated as a single layer, some embodiments may utilize multiple layers. For example, in some embodiments a liner (not separately illustrated) may first be formed along a surface of the substrate 300, the fin structures 308, and the nanostructures 310. Thereafter, a fill material, such as those discussed above may be formed over the liner.

A removal process is then applied to the insulation material to remove excess insulation material over the nanostructures 310. In some embodiments, a planarization process such as a chemical mechanical polish (CMP), an etch-back process, combinations thereof, or the like may be utilized. The planarization process exposes the nanostructures 310 such that top surfaces of the nanostructures 310 and the insulation material are level after the planarization process is complete.

The insulation material is then recessed to form the STI regions 312. The insulation material is recessed such that upper portions of nanostructures 310 protrude from between neighboring STI regions 312. Further, the top surfaces of the STI regions 312 may have a flat surface as illustrated, a convex surface, a concave surface (such as dishing), or a combination thereof. The top surfaces of the STI regions 312 may be formed flat, convex, and/or concave by an appropriate etch. The STI regions 312 may be recessed using an acceptable etching process, such as one that is selective to the material of the insulation material (e.g., etches the material of the insulation material at a faster rate than the material of the nanostructures 310). For example, an oxide removal using, for example, dilute hydrofluoric (dHF) acid may be used.

The process described above with respect to FIGS. 17 through 19 is just one example of how the fin structures 308 and the nanostructures 310 may be formed. In some embodiments, the fin structures 308 and/or the nanostructures 310 may be formed using a mask and an epitaxial growth process. For example, a dielectric layer can be formed over a top surface of the substrate 300, and trenches can be etched through the dielectric layer to expose the underlying substrate 300. Epitaxial structures can be epitaxially grown in the trenches, and the dielectric layer can be recessed such that the epitaxial structures protrude from the dielectric layer to form the fin structures 308 and/or the nanostructures 310. The epitaxial structures may include the sacrificial layers and the single crystal layer discussed above. In some embodiments where epitaxial structures are epitaxially grown, the epitaxially grown materials may be in situ doped during growth, which may obviate prior and/or subsequent implantations, although in situ and implantation doping may be used together.

Further in FIG. 19, appropriate wells (not separately illustrated) may be formed in the substrate 300. After one or more well implants of the substrate 300, an anneal may be performed to repair implant damage and to activate the p-type and/or n-type impurities that were implanted.

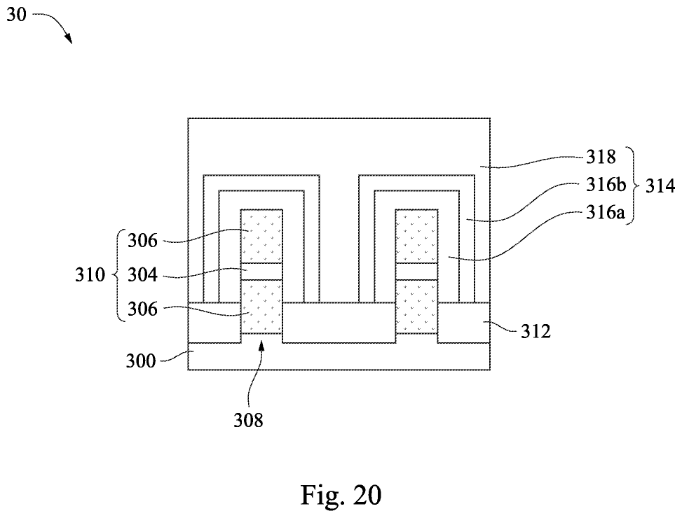

In FIG. 20, a gate stack 314 including gate dielectrics 316a, 316b and a gate layer 318 is formed on the fin structures 308 and the nanostructures 310. In some embodiments, the gate dielectrics 316a, 316b include high-k dielectric material having a high dielectric constant, for example, greater than that of thermal silicon oxide (˜3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide, strontium titanate, hafnium oxynitride (HfOₓN_{y}), other suitable metal-oxides, or combinations thereof. The gate dielectrics 316a, 316b may be formed by ALD, CVD, physical vapor deposition (PVD), remote plasma CVD (RPCVD), plasma enhanced CVD (PECVD), MOCVD, sputtering, other suitable processes, or combinations thereof.

The gate layer 318 may be deposited over the gate dielectrics 316a, 316b and then planarized, such as by a CMP. The gate layer 318 may be similar to the gate electrode 214 in terms of composition, and thus the description thereof is omitted. The gate layer 318 may be deposited by PVD, CVD, sputter deposition, or other techniques for depositing the selected material.

In FIG. 21, a mask layer (not shown) may be formed on the gate layer 318 and then patterned using acceptable photolithography and etching techniques to form masks. The pattern of the mask then may be transferred to the gate layer 318 and to the gate dielectrics 316a, 316b, respectively. The gate layer 318 covers channel region of the fin structures 308. The gate layer 318 may also have a lengthwise direction substantially perpendicular to the lengthwise direction of respective fin structures 308.

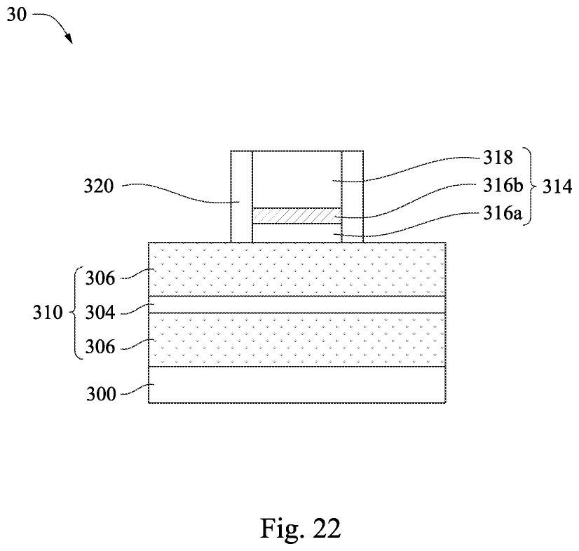

A spacer layer is formed over the structures illustrated in FIG. 21. The spacer layer may be formed of silicon oxide, silicon nitride, silicon oxynitride, or the like, using CVD, ALD, PVD or the like. The spacer layer may be etched using a suitable etching process, such as an isotropic etching process (e.g., a wet etching process), an anisotropic etching process (e.g., a dry etching process), or the like. The spacer layer will be subsequently etched to act as spacers 320 for forming self-aligned source/drain regions. The resulting structure is shown in FIG. 22.

As will be discussed in greater detail below, the spacers 320 act to self-align subsequently formed source drain regions, as well as to protect sidewalls of the fin structures 308 and/or nanostructure 310 during subsequent processing.

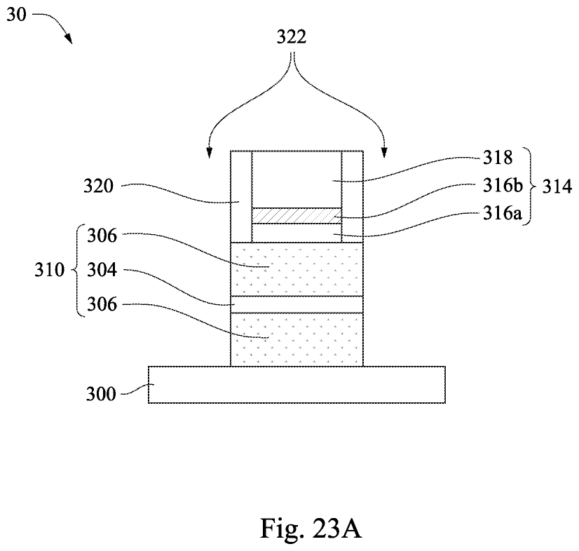

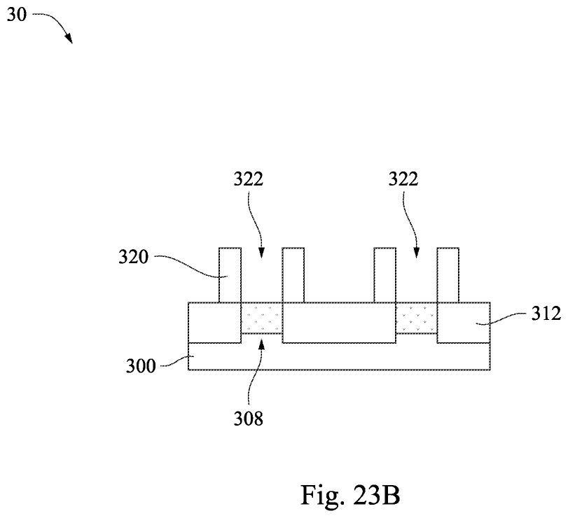

In FIGS. 23A and 23B, source/drain recesses 322 are formed in the fin structures 308 and/or the nanostructures 310, in accordance with some embodiments. Epitaxial source/drain regions will be subsequently formed in the source/drain recesses 322. The source/drain recesses 322 may extend through the nanostructures 310. As illustrated in FIG. 23B, bottom surfaces of the source/drain recesses 322 may be level with top surfaces of the STI regions 312, as an example. In some other embodiments, the fin structures 308 may be etched such that bottom surfaces of the source/drain recesses 322 are disposed below the top surfaces of the STI regions 312 or above the top surfaces of the STI regions 312. The source/drain recesses 322 may be formed by etching the fin structures 308 and the nanostructures 310 using anisotropic etching processes, such as RIE, NBE, or the like. The spacers 320 mask portions of the fin structures 308, the nanostructures 310, and the substrate 300 during the etching processes used to form the source/drain recesses 322. A single etch process or multiple etch processes may be used to etch each layer of the nanostructures 310 and/or the fin structures 308. Timed etch processes may be used to stop the etching of the source/drain recesses 322 after the source/drain recesses 322 reach a target depth.

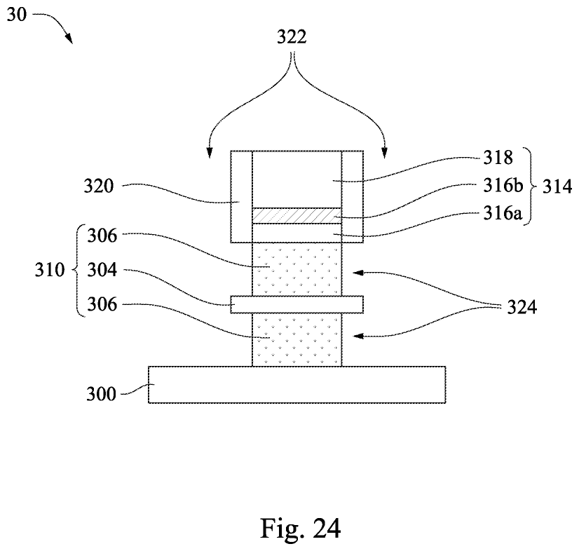

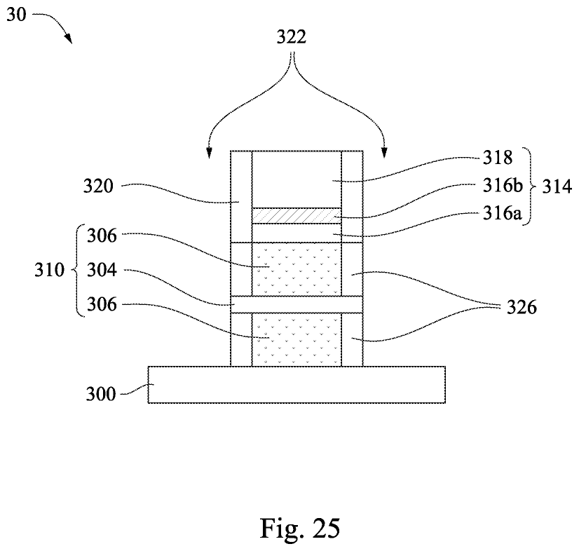

In FIG. 24, sidewalls of the nanostructures 310 exposed by the source/drain recesses 322 are etched to form sidewall recesses 324. Although sidewalls of the nanostructures 310 in the sidewall recesses 324 are illustrated as being straight in FIG. 24, the sidewalls may be concave or convex. The sidewalls may be etched using isotropic etching processes, such as wet etching or the like.

In FIG. 25, inner spacers 326 are formed in the sidewall recess 324. The inner spacers 326 may be formed by depositing an inner spacer layer (not separately illustrated) over the structures illustrated in FIG. 24. The inner spacers 326 act as isolation features between subsequently formed source/drain regions and gate structure. As will be discussed in greater detail below, source/drain regions will be formed in the source/drain recesses 322, and the sacrificial layers 306 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 326. Although outer sidewalls of the inner spacers 326 are illustrated as being flush with sidewalls of the single crystal layer 304, the outer sidewalls of the inner spacers 326 may extend beyond or be recessed from sidewalls of the single crystal layer 304.

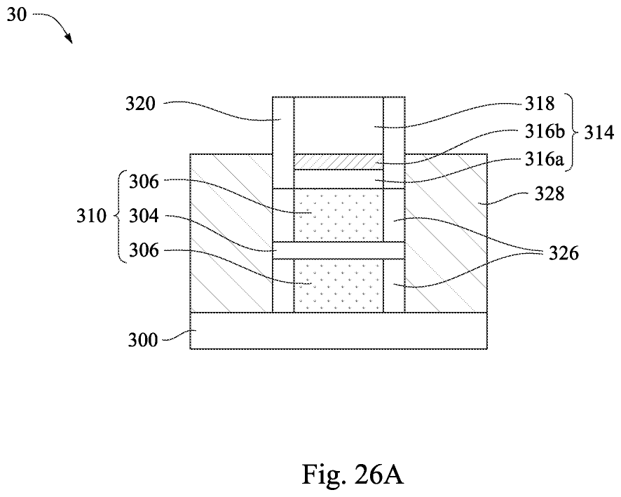

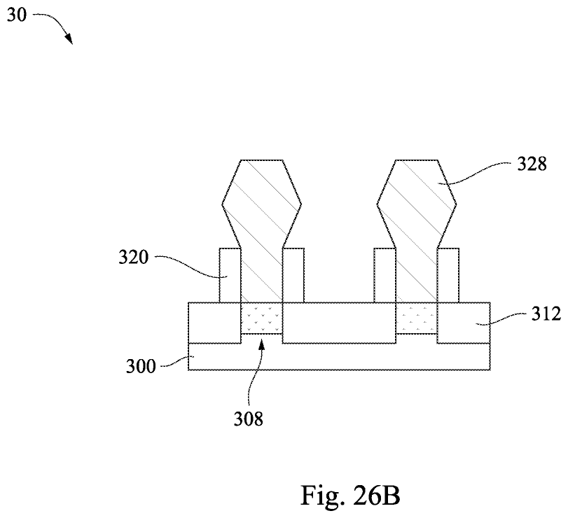

Moreover, although the outer sidewalls of the inner spacers 326 are illustrated as being straight in FIG. 25, the outer sidewalls of the inner spacers 326 may be concave or convex. The inner spacer layer may be etched by an anisotropic etching process, such as RIE, NBE, or the like. The inner spacers 326 may be used to prevent damage to subsequently formed source/drain regions (such as the epitaxial source/drain regions 328, discussed below with respect to FIG. 26A) by subsequent etching processes, such as etching processes used to form gate structures.

In FIGS. 26A-26B, epitaxial source/drain regions 328 are formed in the source/drain recesses 322. In some embodiments, the epitaxial source/drain regions 328 may exert stress on the single crystal layer 304, thereby improving device performance. In some embodiments, the spacers 320 are used to separate the epitaxial source/drain regions 328 from the gate layer 318 and the inner spacers 326 are used to separate the epitaxial source/drain regions 328 from the sacrificial layers 306 by an appropriate lateral distance so that the epitaxial source/drain regions 328 do not short out with subsequently formed gates of the resulting GAA-FETs.

In some embodiments, the epitaxial source/drain regions 328 may include any acceptable material appropriate for n-type GAA-FETs. For example, the epitaxial source/drain regions 328 may include materials exerting a tensile strain on the single crystal layer 304, such as SiP, or the like. In some embodiments, the epitaxial source/drain regions 328 may include any acceptable material appropriate for p-type GAA-FETs. For example, the epitaxial source/drain regions 328 may include materials exerting a compressive strain on the single crystal layer 304, such as GeSnB and/or SiGeSnB, or the like. The epitaxial source/drain regions 328 may have surfaces raised from respective upper surfaces of the nanostructures 310 and may have facets.

The epitaxial source/drain regions 328 may be implanted with dopants to form source/drain regions, followed by an anneal. The n-type and/or p-type impurities for source/drain regions may be any of the impurities previously discussed. In some embodiments, the epitaxial source/drain regions 328 may be in situ doped during growth.

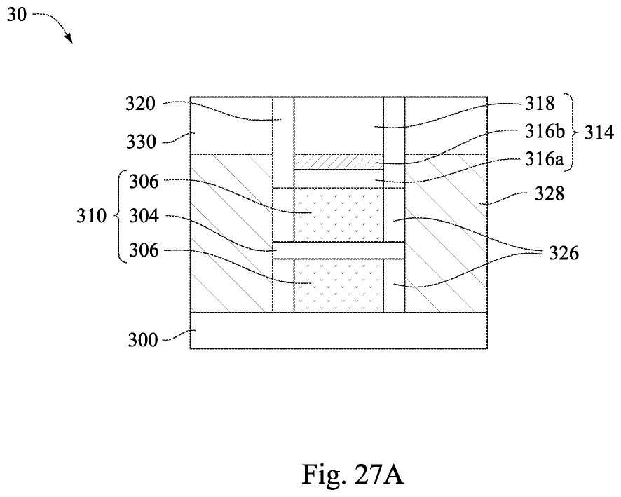

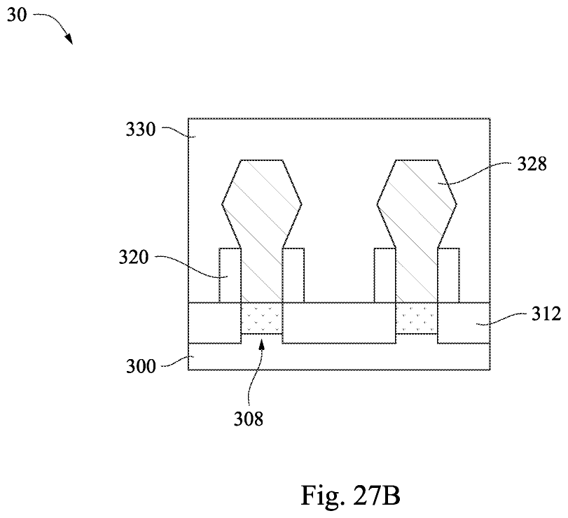

In FIGS. 27A-27B, an interlayer dielectric (ILD) layer 330 is deposited over the structure illustrated in FIGS. 26A-26B. The ILD layer 330 may be formed of a dielectric material, and may be deposited by any suitable method, such as CVD, PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (not illustrated) is disposed between the ILD layer 330 and the epitaxial source/drain regions 328 and the spacers 320. The contact etch stop layer may include a dielectric material, such as, silicon nitride, silicon oxide, silicon oxynitride, or the like, having a different etch rate than the material of the overlying ILD layer 330.

A planarization process, such as a CMP, may be performed to level the top surface of the ILD layer 330 with the top surfaces of the gate layer 318. After the planarization process, top surfaces of the gate layer 318, the spacers 320, and the ILD layer 330 are level within process variations. Accordingly, the top surfaces of the gate layer 318 are exposed through the ILD layer 330.

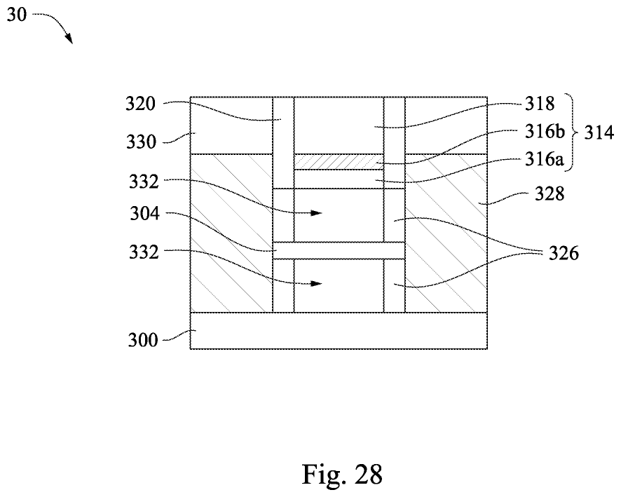

In FIG. 28, the sacrificial layers 306 are removed by an isotropic etching process such as wet etching or the like using etchants which are selective to the materials of the sacrificial layers 306. Stated differently, the sacrificial layers 306 are removed by using a selective etching process that etches the sacrificial layers 306 at a faster etch rate than it etches the single crystal layer 304, thus forming spaces between the sacrificial layers 306 (also referred to as sheet-sheet spaces if the single crystal layer 304 is nanosheet). This step can be referred to as a channel release process. At this interim processing step, the spaces 332 between the single crystal layer 304 and the substrate 300 and between the single crystal layer 304 and the gate dielectrics 316a, 316b may be filled with ambient environment conditions (e.g., air, nitrogen, etc). In some embodiments, the single crystal layer 304 can be referred to as nanosheets, nanowires, nanoslabs, nanorings having nano-scale size (e.g., a few nanometers), depending on their geometry. For example, in some embodiments the single crystal layer 304 may be trimmed to have a substantial rounded shape (i.e., cylindrical) due to the selective etching process for completely removing the sacrificial layers 306. In that case, the resultant single crystal layer 304 can be called nanowires.

In some embodiments, both the channel release step and the previous step of laterally recessing single crystal layer 304 (i.e., the step as illustrated in FIG. 24) use a selective etching process that etches the sacrificial layers 306 at a faster etch rate than etching single crystal layer 304, and therefore these two steps may use the same etchant chemistry in some embodiments. In this case, the etching time/duration of channel release step is longer than the etching time/duration of the previous step of laterally recessing sacrificial layers 306, so as to completely remove the sacrificial layers 306.

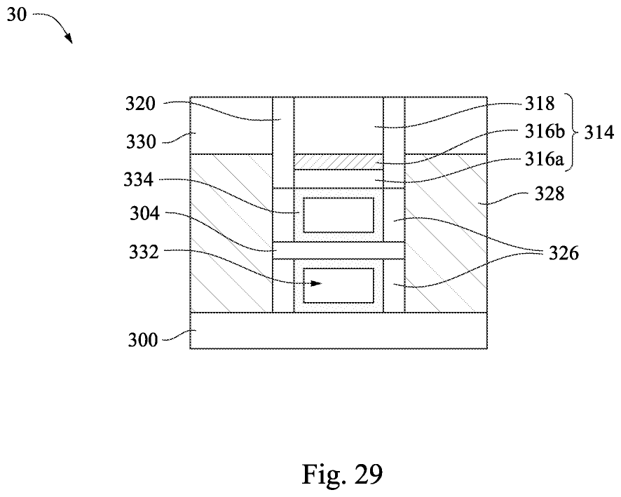

Reference is made to FIG. 29. A dielectric layer 334 is deposited conformally in the spaces 332. The single crystal layer 304 is a single crystal 2D material such as 2D metallic material, a 2D dielectric, or a 2D semiconductor, as discussed previously with regard to FIG. 1. The single crystal layer 304 has a lattice constant similar to a lattice constant of the dielectric layer 334 in order to advantageously allow the dielectric layer 334 formed as a single crystal, discussed previously with regard to FIG. 2. The dielectric layer 334 is a single crystal dielectric layer with ferroelectric (FE) phase or antiferroelectric (AFE) phase. In some embodiments, the dielectric layer 334 includes doped HfO₂, ZrO₂, Hf₁₋ₓZrₓO₂ where 0<x<1, with a defined grain orientation with FE phase or AFE phase.

In FIG. 30, a gate layer 336 is formed to fill a remainder of spaces 332. The gate layer 336 is similar to the gate layer 318 in terms of composition and formation, and thus the description thereof is omitted. The semiconductor device 30 includes one single crystal layer 304, thereby forming a single-channel gate all around (GAA) transistor.

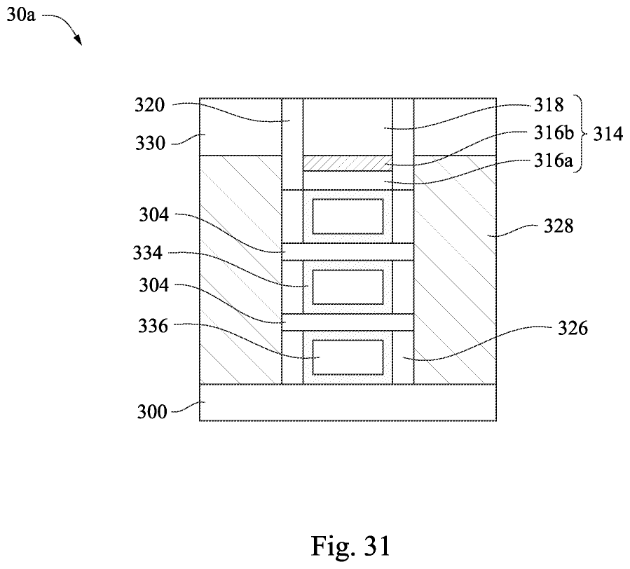

FIG. 31 is a cross-sectional view of a semiconductor device 30a in accordance with some embodiments. The semiconductor device 30a is similar to the semiconductor device 30 with regard to FIG. 30, except for including multiple single crystal layers 304. For example, the semiconductor device 30a includes two single crystal layers 304, thereby forming a multi-channel gate all around (GAA) transistor.

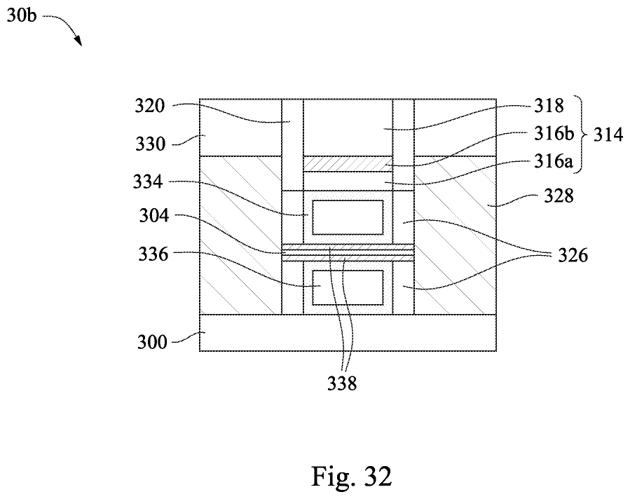

FIG. 32 is a cross-sectional view of a semiconductor device 30b in accordance with some embodiments. The semiconductor device 30b is similar to the semiconductor device 30 with regard to FIG. 30, except for further including crystalline insulators 338. The single crystal layer 304 is sandwiched between the crystalline insulators 338 in a direction perpendicular to the substrate 300.

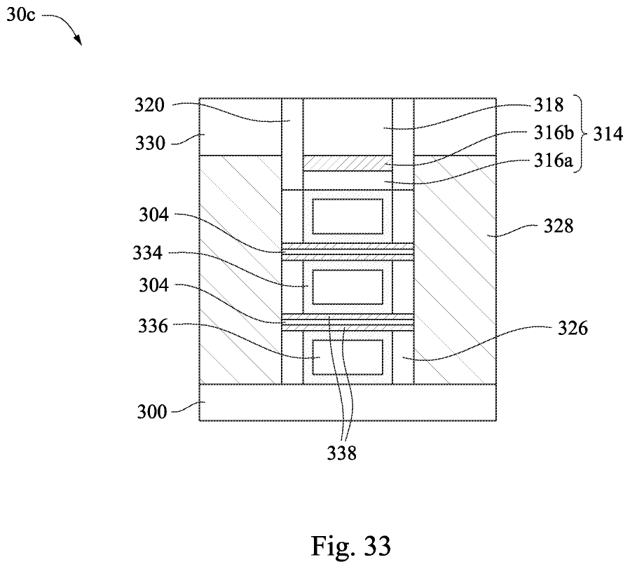

FIG. 33 is a cross-sectional view of a semiconductor device 30c in accordance with some embodiments. The semiconductor device 30c is similar to the semiconductor device 30b with regard to FIG. 32, except for including multiple single crystal layers 304. For example, the semiconductor device 30c includes two single crystal layers 304, thereby forming a multi-channel gate all around (GAA) transistor.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that by forming the dielectric layer on the substrate which is a single crystal substrate and has a lattice constant similar to a lattice constant of the dielectric layer, the dielectric layer can be formed as with defined grain orientation with ferroelectric phase or antiferroelectric phase. Another advantage is that the substrate includes a single crystal 2D material such as 2D metallic material, a 2D dielectric, or a 2D semiconductor, or includes a single crystal metal such as single crystal Hf, single crystal Mo or single crystal W which are used in a wide variety of commercial electronic devices, and thus is compatible with a commercial process flow.

In some embodiments, an epitaxial structure comprises a substrate comprising a single crystal metal or a single crystal 2D material and a dielectric layer on the substrate. The dielectric layer is in physical contact with the substrate and comprises a non-perovskite structure with defined grain orientation with ferroelectric (FE) phase or antiferroelectric (AFE) phase. In some embodiments, the substrate is a single crystal metal including Mo, W. Zr or Hf. In some embodiments, the substrate is a single crystal 2D material including layered Hf, h-AlN, MoS₂ or WS₂. In some embodiments, the dielectric layer has a (111) surface orientation. In some embodiments, the substrate is not La₁₋ₓSrₓMnO₃.

In some embodiments, a semiconductor device comprises a single crystal substrate, a single crystal dielectric layer including HFO₂, ZrO₂, or Hf₁₋ₓZrₓO₂ where 0<x<1, grown on the single crystal substrate, and a layer on the single crystal dielectric layer. The layer includes semiconductor or metal. In some embodiments, the single crystal substrate has a crystal system different from a crystal system of the single crystal dielectric layer. In some embodiments, the single crystal substrate has a hexagonal crystal structure, and the single crystal dielectric layer has a cubic structure. In some embodiments, the single crystal substrate and the single crystal dielectric layer have the same crystal system. In some embodiments, the same crystal system is cubic crystal structure. In some embodiments, the semiconductor device further comprises a crystalline insulator disposed between the single crystal substrate and the single crystal dielectric layer. In some embodiments, the semiconductor device further comprises source/drain electrodes on the layer, wherein the layer includes semiconductor. In some embodiments, the semiconductor device further comprises gate spacers on opposite sidewalls of the layer and source/drain epitaxial structures below the layer and abutting the single crystal substrate. The layer includes metal. In some embodiments, the semiconductor device further comprises a crystalline insulator between the single crystal substrate and the single crystal dielectric layer.

In some embodiments, a method of forming an epitaxial structure includes the following steps. A deposition process is performed to epitaxialy grow a single crystal dielectric layer having a (111) surface orientation on a substrate. The deposition process is atomic layer deposition, metal organic chemical vapor deposition, or molecular beam epitaxy. The substrate is a single crystal metal or a single crystal 2D material, and the single crystal dielectric layer is a ferroelectric layer or an antiferroelectric layer. In some embodiments, the deposition process is performed including the following steps. A layer is deposited on the substrate. The layer is doped with Zr atoms to form the single crystal dielectric layer such that the single crystal dielectric layer comprises Hf₁₋ₓZrₓO₂ where 0<x<1. In some embodiments, the single crystal dielectric layer is formed by oxygen monolayers, Zr monolayers and Hf monolayers. In some embodiments, the substrate is a single crystal metal including Mo, W, Zr or Hf. In some embodiments, the substrate is a single crystal 2D material including layered Hf, h-AlN, MoS₂ or WS₂. In some embodiments, the substrate and the single crystal dielectric layer have different crystal systems.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An epitaxial structure, comprising:
a substrate comprising a single crystal metal or a single crystal 2D material; and
a dielectric layer on the substrate, wherein the dielectric layer is in physical contact with the substrate and comprises a non-perovskite structure with defined grain orientation with ferroelectric (FE) phase or antiferroelectric (AFE) phase.

2. The epitaxial structure of claim 1, wherein the substrate is a single crystal metal including Mo, W, Zr or Hf.

3. The epitaxial structure of claim 1, wherein the substrate is a single crystal 2D material including layered Hf, h-AlN, MoS₂ or WS₂.

4. The epitaxial structure of claim 1, wherein the dielectric layer has a (111) surface orientation.

5. The epitaxial structure of claim 1, wherein the substrate is not La₁₋ₓSr_{X}MnO₃.

6. A semiconductor device, comprising:
a single crystal substrate;
a single crystal dielectric layer including HFO₂, ZrO₂, or Hf₁₋ₓZrₓO₂ where 0<x<1, grown on the single crystal substrate; and
a layer on the single crystal dielectric layer, wherein the layer includes semiconductor or metal.

7. The semiconductor device of claim 6, wherein the single crystal substrate has a crystal system different from a crystal system of the single crystal dielectric layer.

8. The semiconductor device of claim 7, wherein the single crystal substrate has a hexagonal crystal structure, and the single crystal dielectric layer has a cubic structure.

9. The semiconductor device of claim 6, wherein the single crystal substrate and the single crystal dielectric layer have the same crystal system.

10. The semiconductor device of claim 9, wherein the same crystal system is cubic crystal structure.

11. The semiconductor device of claim 6, further comprising:
a crystalline insulator disposed between the single crystal substrate and the single crystal dielectric layer.

12. The semiconductor device of claim 6, further comprising:
source/drain electrodes on the layer, wherein the layer includes semiconductor.

13. The semiconductor device of claim 6, further comprising:
gate spacers on opposite sidewalls of the layer, wherein the layer includes metal; and
source/drain epitaxial structures below the layer and abutting the single crystal substrate.

14. The semiconductor device of claim 13, further comprising:
a crystalline insulator between the single crystal substrate and the single crystal dielectric layer.

15. A method of forming an epitaxial structure, comprising:
performing a deposition process to epitaxially grow a single crystal dielectric layer having a (111) surface orientation on a substrate, wherein the deposition process is atomic layer deposition, metal organic chemical vapor deposition, or molecular beam epitaxy, and wherein:
the substrate is a single crystal metal or a single crystal 2D material, and the single crystal dielectric layer is a ferroelectric layer or an antiferroelectric layer.

16. The method of claim 15, wherein performing the deposition process comprises:
depositing a layer on the substrate; and
doping the layer with Zr atoms to form the single crystal dielectric layer such that the single crystal dielectric layer comprises Hf₁₋ₓZrₓO₂ where 0<x<1.

17. The method of claim 15, wherein the single crystal dielectric layer is formed by oxygen monolayers, Zr monolayers and Hf monolayers.

18. The method of claim 15, wherein the substrate is a single crystal metal including Mo, W, Zr or Hf.

19. The method of claim 15, wherein the substrate is a single crystal 2D material including layered Hf, h-AlN, MoS₂ or WS₂.

20. The method of claim 15, wherein the substrate and the single crystal dielectric layer have different crystal systems.
